(19) United States
(12) Patent Application Publication
(10) Pub. No.: US 2015/0155427 A1
(43) Pub. Date: Jun. 4, 2015

(54) METHOD OF MANUFACTURING LIGHTING DEVICE

(71) Applicant: SAMSUNG ELECTRONICS CO., LTD., Suwon-si (KR)

(72) Inventors: June JANG, Seoul (KR); Seung Gyun JUNG, Suwon-si (KR); Ki Un LEE, Hwaseong-si (KR)

(21) Appl. No.: 14/454,519

(22) Filed: Aug. 7, 2014

(30) Foreign Application Priority Data
Dec. 2, 2013 (KR) 10-2013-0148831

(51) Int. Cl. H01L 33/00

(52) U.S. Cl. CPC H01L 33/005; H01L 2933/0025; H01L 2933/0033; H01L 2933/005; H01L 2933/0058; H01L 2933/0075

(57) ABSTRACT

A method of manufacturing a lighting device includes filling a plurality of concave portions formed in a mold by applying a liquid-phase resin to the mold. A light transmitting sheet is attached to cover the liquid-phase resin. A plurality of lenses is formed by curing the liquid-phase resin. The light transmitting sheet on which the plurality of lenses are formed is separated from the mold. The light transmitting sheet is cut. A light emitting module is prepared including a body portion containing a plurality of light emitting devices and a groove portion spaced apart from the plurality of light emitting devices, and slidably coupling the cut light transmitting sheet to the groove portion so as to allow positions of the plurality of light emitting devices to be aligned with positions of the plurality of lenses.

### CROSS-REFERENCE TO RELATED APPLICATION

This application claims priority to, and benefit of Korean Patent Application No. 10-2013-0148831 filed on Dec. 2, 2013, with the Korean Intellectual Property Office, the entire content of which is hereby incorporated by reference.

### TECHNICAL FIELD

The present disclosure relates to a method of manufacturing a lighting device and a method of manufacturing a lens portion in the lighting device.

### BACKGROUND

Light emitting diodes (LED) are devices in which a material contained therein emits light using electrical energy by converting energy generated through the recombination of electrons and holes at junctions between semiconductors into light. Such light emitting diodes have been extensively used in general illumination devices and display devices as light sources, and the development thereof has been accelerated accordingly.

In recent times, the development of light emitting diodes, for example, gallium nitride-based LEDs, commercialized for use in mobile phone keypads, vehicle turn signal lamps, camera flashes, and the like, has accelerated. Accordingly, the development of general illumination devices utilizing light emitting diodes has been actively undertaken. As the application of LEDs has broadened from relatively small products to relatively large products, in products such as backlight units for large sized television sets, vehicle headlights, general illumination devices, and the like, LEDs have also been developed as large sized, highly-efficient, high-output products.

Meanwhile, in order to control the light distribution of light emitting diodes, various types of lens may be combined with such LED-containing products. Accordingly, a manufacturing method of a lighting device for reducing lens manufacturing costs has been in demand.

### SUMMARY

An aspect of the present disclosure may provide a method of manufacturing a lighting device, for facilitating manufacturing thereof as well as reducing manufacturing costs thereof.

One aspect of the present disclosure relates to a method of manufacturing a lighting device, including filling a plurality of first concave portions formed in one surface of a first mold by applying a first liquid-phase resin to the first mold. A light transmitting sheet is attached to a surface of the first liquid-phase resin to cover the first liquid-phase resin filling the first concave portions. A plurality of lenses are formed on one surface of the light transmitting sheet by curing the first liquid-phase resin. The light transmitting sheet on which the plurality of lenses are formed is separated from the first mold. The light transmitting sheet is cut into predetermined units to allow the plurality of lenses to be aligned in a single direction. A light emitting module is prepared including a body portion containing a plurality of light emitting devices aligned in a single direction on one surface of the body portion and a groove portion spaced apart from the plurality of light emitting devices by a predetermined interval and extending in a single direction, and slidably coupling the cut light transmitting sheet to the groove portion so as to allow positions of the plurality of light emitting devices to be aligned with positions of the plurality of lenses to coincide with each other.

According to the method of manufacturing a lighting device , after the separating of the light transmitting sheet from the first mold, a second liquid-phase resin may be applied to a second mold including second concave portions formed in regions of the second mold corresponding to positions of the lenses formed from the first mold to fill the second concave portions. The other surface of the light transmitting sheet may be attached to a surface of the second liquid-phase resin so as to allow positions of the lenses formed from the first mold to be aligned with positions of the second concave portions to coincide.

The first liquid-phase resin may be an ultraviolet (UV) curable resin.

The forming of the lenses may include irradiating ultraviolet light to the first liquid-phase resin.

The first liquid-phase resin may be a silicone resin.

The forming of the lenses may include heating the first liquid-phase resin.

The light transmitting sheet may be formed using polycarbonate (PC) or polyethylene terephthlate (PET).

The light transmitting sheet may include a through hole formed in a region of the light transmitting sheet corresponding to a position of the first concave portion.

The forming of the lenses may be performed by coupling a jig having a convex portion disposed to correspond to a position of the through hole and curing the first liquid-phase resin.

A refractive index of the liquid-phase resin may be different from a refractive index of the light transmitting sheet.

Another aspect of the present disclosure encompasses a method of manufacturing a lighting device including forming a plurality of lenses by sequentially stacking a plurality of sub-layers on a light transmitting sheet in a perpendicular direction with regard to the light transmitting sheet. The light transmitting sheet is cut in a single direction to allow the plurality of lenses to be aligned in a single direction. A light emitting module is prepared including a body portion containing a plurality of light emitting devices aligned in a single direction on one surface of the body portion and a groove portion spaced apart from the plurality of light emitting devices by a predetermined interval and extending in a single direction, and slidably coupling the cut light transmitting sheet to the groove portion so as to allow positions of the plurality of light emitting devices to be aligned with positions the plurality of lenses.

The plurality of sub-layers may be in parallel to light incident surfaces of the lenses.

The plurality of sub-layers may be formed by applying and curing the liquid-phase resin.

The liquid-phase resin may be a liquid-phase UV curable resin or a silicone resin.

The light transmitting sheet may be formed using polycarbonate (PC) or polyethylene terephthlate (PET).

Still another aspect of the present disclosure encompasses a method of manufacturing a lamp including manufacturing a plurality of lighting devices manufactured according to the above-noted method. A light emitting module may be prepared to include a circuit board and directly mounting the plurality of lighting devices on the circuit board. A heat radiating plate may be prepared so that the light emitting module having the plurality of lighting devices mounted thereon is in direct contact with the heat radiating plate. A cover unit may be mounted on the light emitting module.

Still another aspect of the present disclosure relates to method of manufacturing a lens portion including forming a plurality of first lenses on a first surface of a light transmitting sheet. A plurality of concave portions formed on a mold are filled by applying a liquid-phase resin to the mold so that positions of the concave portions correspond to respective positions of the first lenses on the light transmitting sheet. A second surface of the light transmitting sheet is attached to a surface of the liquid-phase resin so that the positions of the concave portions correspond to the respective positions of the first lenses on the light transmitting sheet. After attaching the second surface of the light transmitting sheet to the surface of the liquid-phase resin, a plurality of second lenses are formed on the second surface of the light transmitting sheet by curing the liquid-phase resin.

The light transmitting sheet on which the plurality of first lenses and the plurality of second lenses are formed, may be separated from the mold.

The light transmitting sheet may be cut into predetermined units to allow the plurality of first lenses and the plurality of second lenses to be aligned in a single direction.

Still another aspect of the present disclosure encompasses a method of manufacturing a lighting device including manufacturing a light transmitting sheet according to the above-noted method. A light emitting module may be prepared including a body portion containing a plurality of light emitting devices aligned in a single direction on one surface of the body portion and a groove portion spaced apart from the plurality of light emitting devices by a predetermined interval and extending in a single direction. The light transmitting sheet may be slidably coupled to the groove portion so that positions of the plurality of light emitting devices correspond to respective positions of the plurality of first lenses.

### BRIEF DESCRIPTION OF THE DRAWINGS

The above and other aspects, features and other advantages will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is an exploded perspective view of a lighting device according to an exemplary embodiment of the present inventive concept.

FIG. 2 is a side cross-sectional view of a lens portion taken along line A-A′ of FIG. 1.

FIGS. 3 to 5 illustrate modified examples of the lens portion illustrated in FIG. 1.

FIGS. 6 to 12 are views illustrating a manufacturing method of a lens portion illustrated in FIG. 4.

FIGS. 13 to 15 are views illustrating a manufacturing method of a lens portion of FIG. 3.

FIGS. 16 to 19 are views illustrating a manufacturing method of a lens portion of FIG. 5.

FIG. 20 is an exploded perspective view of a lighting device according to another exemplary embodiment of the present inventive concept.

### DETAILED DESCRIPTION

Exemplary embodiments of the present inventive concept will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

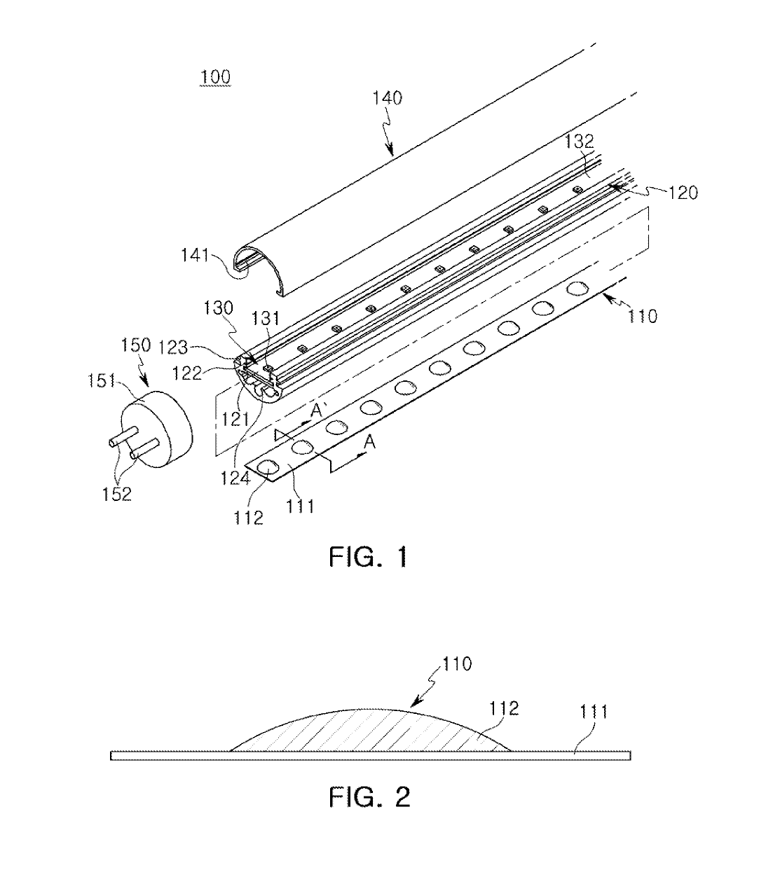

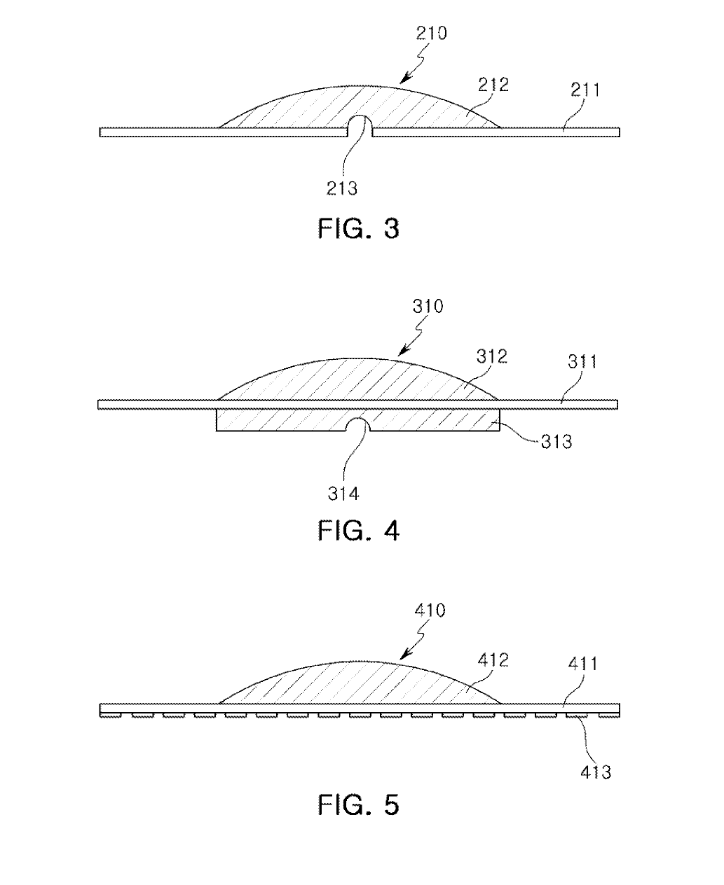

FIG. 1 is an exploded perspective view of a lighting device according to an exemplary embodiment of the present inventive concept, FIG. 2 is a side cross-sectional view of a lens portion taken along line A-A′ of FIG. 1, and FIGS. 3 to 5 illustrate modified examples of the lens portion illustrated in FIG. 1.

With reference to FIGS. 1 and 2, a lighting device 100, according to an exemplary embodiment of the present inventive concept, may include a lens portion 110, a body portion 120, a light emitting module 130, a cover portion 140 and a terminal portion 150.

The body portion 120 may serve as a support member on which the light emitting module 130 is fixedly mounted. The body portion 120 may be defined by the entirety of the lighting device 100.

As illustrated in FIGS. 1 and 2, the body portion 120 may include the light emitting module 130 fixed to one surface thereof by a groove portion 121, and may discharge heat generated in the light emitting module 130 externally. Therefore, the body portion 120 may function as a heat sink, a support structure, and may have a hollow pipe shape. The body portion 120 may include a plurality of radiating fins 124 protruding from an inner surface of the body portion 120 so as to radiate heat.

The body portion 120 may have a lengthwise elongated rod shape. The body portion 120 may be formed using a material having excellent thermal conductivity so as to facilitate the discharge of heat generated in the light emitting module 130 externally, and, for example, may be made of a metal such as aluminum (Al), but the present inventive concept is not limited thereto.

The cover portion 140 may be fastened to the body portion 120 to be detachable. The cover portion 140 may be slidably coupled to a groove portion 123 formed in the body portion 120 using protrusion portion 141. The cover portion 140 may be formed using a light transmitting material to allow light generated in the light emitting module 130 to be irradiated externally. As a material of the cover portion 140, glass, a transparent resin, an opaque resin, or the like may be used, but the present inventive concept is not limited thereto.

The cover portion 140 may cover and protect the light emitting module 130 from external environments and may allow light generated in the light emitting module 130 to be refracted and irradiated across a wide region. In addition, the cover portion 140 may contain a light diffusing material to diffuse light. As the light diffusing material, for example, titanium dioxide (TiO₂) or the like may be used.

The body portion 120 including the cover portion 140 fastened thereto, may have, for example, a cylindrical tube shape corresponding to the shape of existing fluorescent lamps so that the lighting device according to an embodiment of the present inventive concept can replace such existing fluorescent lamps. The body portion 120 may have various shapes in addition to the shape described above.

The body portion 120 may include the groove portion 121 formed in one surface thereof in which the light emitting module 130 is fixedly mounted, and the light emitting module 130 may be slidably coupled to the groove portion 121. The light emitting module 130 may include a substrate 132 and a plurality of light emitting devices 131 mounted on the substrate 132. The light emitting module 130 may apply an electrical signal to the plurality of light emitting devices 131 through an electrical connection via the terminal portion 150.

The substrate 132 may be a general FR4-type printed circuit board (PCB), may be formed using an organic resin material containing epoxy, triazine, silicone, polyimide, or the like, or other organic resin materials, may be formed using a ceramic material such as silicon nitride, AlN, Al₂O₃ or the like, or may be formed using a metal or a metal compound. In addition, the substrate 132 may be a metal-core printed circuit board (MCPCB) or a metal copper clad laminate (MCCL) board.

As the light emitting device 131, any device may be used as long as it is a photoelectric element generating light having a predetermined wavelength through external power applied thereto. For example, the light emitting device 131 may include a semiconductor light emitting diode (LED) obtained by epitaxially growing a semiconductor layer on a growth substrate. The light emitting device 131 may emit blue light, green light or red light according to a material contained therein and may also emit white light.

For example, the light emitting device 131 may have a structure in which an n-type semiconductor layer, a p-type semiconductor layer and an active layer interposed between the n-type and p-type semiconductor layers are stacked on each other, but the present inventive concept is not limited thereto. In this case, the active layer may be configured of a nitride semiconductor containing a material having a composition of, for example, InₓAl_{y}Ga_{1-x-y}N (0≦x≦1, 0≦y≦1, and 0≦x+y≦1) having a single or multiple quantum well structure.

As the light emitting device 131, LED chips having various structures or various types of LED package including LED chips may be used.

The substrate 132 may have a bar shaped plate structure elongated in a lengthwise direction like the shape of the body portion 120. The structure and shape of the substrate may be variously changed depending on a lighting device structure according to an exemplary embodiment of the present inventive concept.

In addition, the plurality of light emitting devices 131 may be aligned at a predetermined interval in a lengthwise direction of the substrate 132. FIG. 1 illustrates an exemplary embodiment of the present inventive concept in which the plurality of light emitting devices 131 are aligned to form a single row, but the present inventive concept is not limited thereto. For example, the plurality of light emitting devices 131 may be aligned in a plurality of rows.

On the other hand, although not shown in FIGS. 1 and 2, the body portion 120 may further include, for example, an electronic device such as a transformer, a sensor, or a bluetooth device.

The terminal portion 150 may be respectively disposed on both end portions of the body portion 120 to receive power applied externally to drive the light emitting module 130.

The terminal portion 150 may include a cap portion 151 having a circumferential surface. One end of the cap portion 151 may have a shape corresponding to that of the cylindrical shape of an end of the body portion 120 including the cover portion 140 coupled thereto. The other end of the cap portion 151 may have a bottom surface defined by the circumferential surface, such that a pair of electrode pins 152 pass through the bottom surface of the cap portion 151 to be extended outwardly thereof.

The cap portions 151 may be inserted and fastened into both open ends of the body portion 120 to close both the open ends. For example, the cap portion 151 may be, for example, a hollow type lid. The cap portion 151 may have a structure in which one end to be inserted into the body portion 120 is open. An outer diameter of the cap portion may at least correspond to an inner diameter of the cylindrical shape of the body portion 120 including the cover portion 140 coupled thereto, or may be smaller than the inner diameter of the cylindrical shape of the body portion 120 including the cover portion 140 coupled thereto, so as to be inserted into the body portion 120.

The lens portion 110 may be configured to include a light transmitting sheet 111 and a lens 112. The lens portion 110 may be slidably coupled to a groove portion 122 formed in the body portion 120.

The light transmitting sheet 111 may be formed using a flexible transparent or translucent material. According to an exemplary embodiment of the present inventive concept, the light transmitting sheet 111 may have a relatively thin plate shape using a material such as polycarbonate (PC) or polyethylene terephthlate (PET), but the present inventive concept is not limited thereto. The light transmitting sheet 111 may be a base layer on which the lens 112 is formed and may have a thickness and a size able to be slidably inserted into the groove portion 122 of the body portion 120.

In addition, as illustrated in FIG. 5, in a lens portion 410, resin layers 413 having various colors may be coated on a surface of a light transmitting sheet 411 on which the lens 412 is not disposed, so as to change a color of light emitted from the semiconductor light emitting device 131. Further, as the resin layer 413 is coated to have a predetermined pattern, the pattern of the resin layer 413 may also be projected in light emitted from the semiconductor light emitting device 131.

The lens 112 may be disposed on a light emission surface of the semiconductor light emitting device 131 to control light distribution of the semiconductor light emitting device 131, and a surface of the lens 112 may have various shapes such as a convex lens, a concave lens, or the like according to light distribution.

In detail, as illustrated in FIG. 2, the lens 112 may be formed to have a convex lens shape on the light transmitting sheet 111, and as illustrated in FIG. 3, in a lens portion 210, the lens 212 may further include a groove portion 213 having a concave lens shape formed in a portion of the lens 212 to pass through a light transmitting sheet 211 so as to control light distribution of light emitted from the semiconductor light emitting device 131. In addition, as illustrated in FIG. 4, a lens 313 may also be disposed below a light transmitting sheet 311 and the lens 313 may include a groove portion 314 having a concave lens shape.

Referring to FIGS. 1 and 2, the lens 112 may be formed by curing a liquid-phase light transmitting material, and in detail, may be formed using an ultraviolet (UV) curable resin or a silicone resin. Since such a UV curable resin or silicone resin is cured by irradiation of UV or heat, the lens 112 may be easily manufacture by applying a liquid-phase resin to a lens shaped mold having a lens shape intagliated therein to then be cured. The lens may also be formed by repetitively stacking a liquid-phase resin. A detailed manufacturing process of the lens 112 will be described below.

Subsequently, a method of manufacturing a lighting device 100 according to an exemplary embodiment of the present inventive concept will be described. FIGS. 6 to 12 are views illustrating a manufacturing method of the lens portion 310 illustrated in FIG. 4.

First, as illustrated in FIG. 6, a first mold 500 including a plurality of first concave portions 510 may be prepared, and a liquid-phase resin 10 may be applied to the first mold 500 to fill the first concave portions 510 using a dispenser D.

The first mold 500 may be a mold for formation of the lens 310 using the liquid-phase resin 10, and may include the plurality of first concave portions 510 formed in one surface thereof. The first mold 500 may be formed using a material that will not be damaged in a subsequent process of curing the liquid-phase resin 10. The liquid-phase resin 10 may be a UV curable resin or a silicone resin. Since the UV curable resin or the silicone resin may be cured by UV irradiation or a comparatively low temperature heating process, the mold using an Al alloy at a relatively low price may be used, as compared with a mold used in a high temperature injection molding process. Thus, in a method of manufacturing a lens through an injecting molding process, lens manufacturing costs may be reduced. In addition, since a lens may also be manufactured only using one surface of the mold, the lens manufacturing costs may be further reduced as compared with an injection molding process using both surfaces of a mold.

The first concave portion 510 may have a shape in which a shape of the lens 310 described above is engraved in intaglio and may have various modified shapes according to light distribution of the semiconductor light emitting device 131 (see FIG. 1).

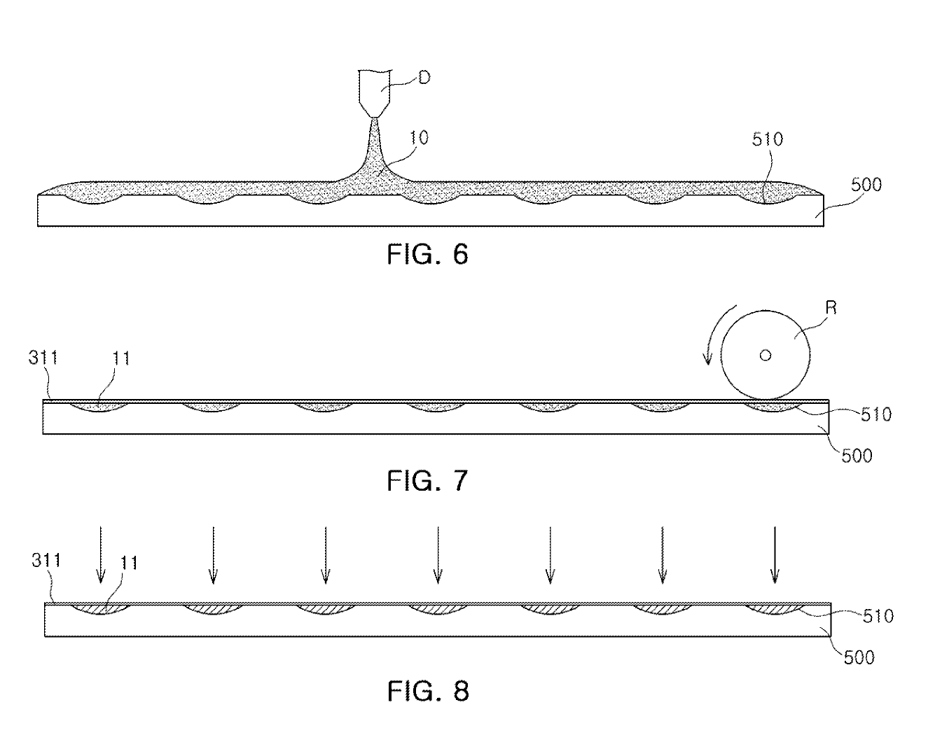

Next, as illustrated in FIG. 7, in order to cover a liquid-phase resin 11, which may be a portion of the liquid-phase resin 10, filling the first concave portions 510, the light transmitting sheet 311 may be attached to a surface of the liquid-phase resin 11. In this case, the surface of the light transmitting sheet 311 may be compressed by a roller R to remove an air layer between the surface of the liquid-phase resin 11 and the surface of the light transmitting sheet 311.

Then, as illustrated in FIG. 8, a plurality of lenses may be formed on one surface of the light transmitting sheet 311 by curing the liquid-phase resin 11. The liquid-phase resin 11 may be cured by irradiation of UV in the case of using a UV curable resin. In addition, when the silicone resin is used as the liquid-phase resin 11, a heating process may be performed to cure the silicone resin.

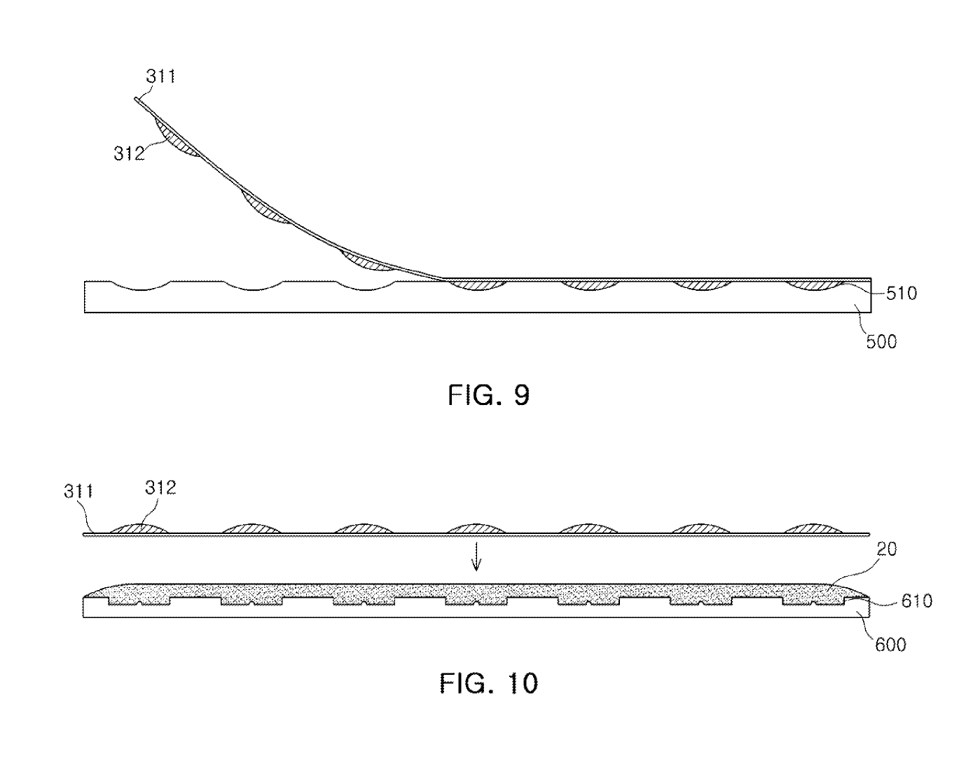

Subsequently, as illustrated in FIG. 9, the light transmitting sheet 311 having the plurality of lenses 312 formed thereon may be separated from the first mold 500.

Then, as illustrated in FIG. 10, a second mold 600 including second concave portions 610 formed in regions thereof corresponding to positions of the lens 312 may be prepared, and a liquid-phase resin 20 may be applied to the second mold to fill the second concave portions 610. The other surface of the light transmitting sheet 311 may then be attached to a surface of the liquid-phase resin 20 so as to allow positions of the lens 312 and the second concave portions 610 to coincide with each other.

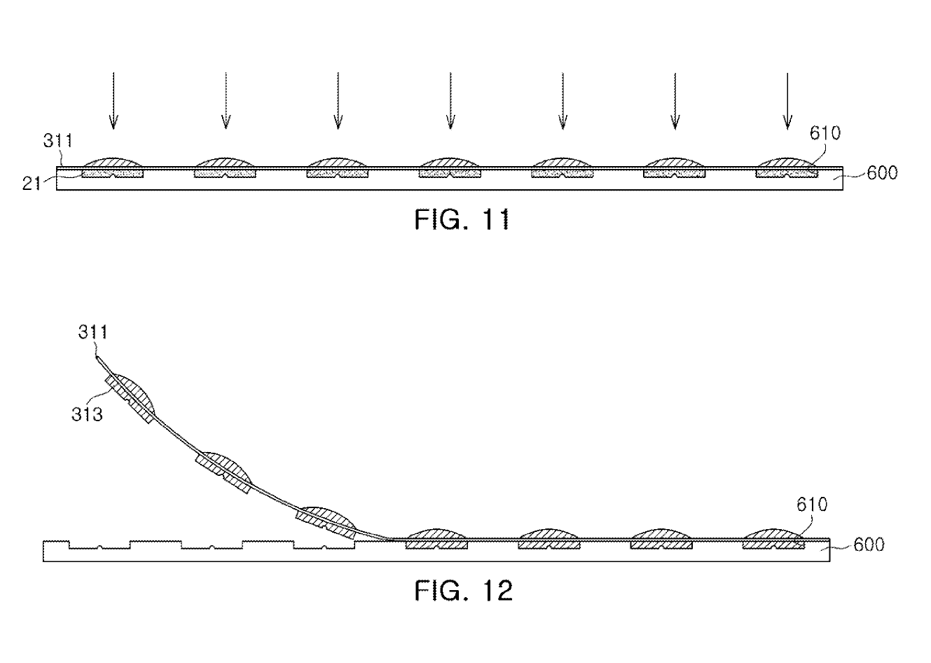

Next, as illustrated in FIG. 11, a liquid-phase resin 21, which may be a portion of the liquid-phase resin 20, applied to the concave portions 610 may be cured, and thereafter, as illustrated in FIG. 12, the light transmitting sheet 311 may be separated from the second mold 600. The light transmitting sheet 311 may then be cut into predetermined units to allow the plurality of lenses 312 to be aligned in a single direction. Then, the light transmitting sheet 311 cut into predetermined units may be slidably coupled to the groove portion 122 of the body portion 120 described above with reference to FIG. 1 to thereby manufacture the lighting device 100 as illustrated in FIG. 1.

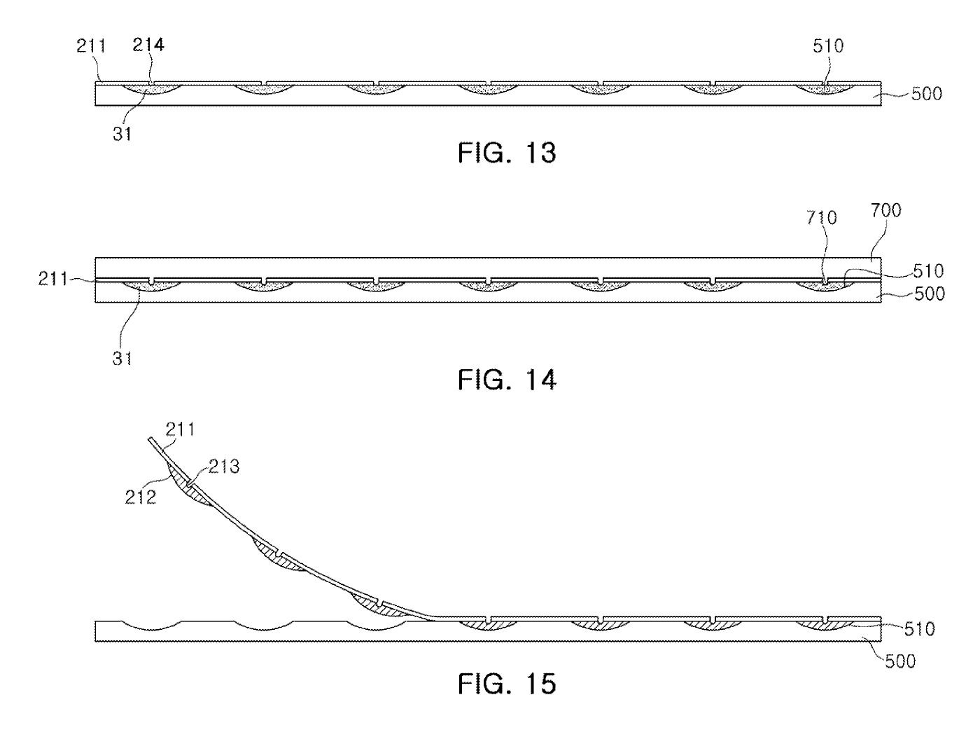

A method of manufacturing a lighting device according to another exemplary embodiment of the present inventive concept will be described below with reference to FIGS. 13 to 15. FIGS. 13 to 15 are views illustrating a manufacturing method of the lens portion 210 of FIG. 3.

In this case, since the method of manufacturing a lighting device with reference to FIGS. 13 to 15 is different from that of the foregoing exemplary embodiment of the present inventive concept only in terms of a lens manufacturing method, this difference will be mainly described below and an overlapped description will be omitted.

First, as described in the foregoing exemplary embodiment of the present inventive concept, a first mold 500 including a plurality of first concave portions 510 formed therein may be prepared, and a liquid-phase resin 10 may be applied to the first mold 500 to fill the first concave portions 510.

Next, as illustrated in FIG. 13, in order to cover a liquid-phase resin 31 filling the first concave portions 510, a light transmitting sheet 211 may be attached to a surface of the liquid-phase resin 31. In this case, unlike the foregoing exemplary embodiment of the present inventive concept, the light transmitting sheet 211 may have a through hole 214 formed in a central region of the first concave portion 510. The through hole 214 may form a groove portion 213 (see FIG. 3) having a concave lens shape in a portion of a lens through coupling of a jig 700 (see FIG. 14) thereto in a subsequent process, and may have a shape corresponding to that of a convex portion 710 (see FIG. 14) of the coupled jig 700.

Then, as illustrated in FIG. 14, the light transmitting sheet 211 may be compressed by the jig 700 thereon so as to allow positions of the through holes 214 of the light transmitting sheet 211 and the convex portions 710 of the jig 700 to coincide with each other, such that an embossed portion of the convex portion 710 may be transcribed to the liquid-phase resin 31 to form the groove portion 213 having a concave lens shape.

Then, as illustrated in FIG. 15, the jig 700 may be removed and the light transmitting sheet 211 including the plurality of lenses 212 formed therein may be separated from the first mold 500.

Next, the light transmitting sheet 211 may be cut in a single direction to allow the plurality of lenses 212 to be aligned in a single direction. The light transmitting sheet 211 cut into predetermined units as above may be slidably coupled to the groove portion 122 of the body portion 120 described above with reference to FIG. 1 to thereby manufacture the lighting device 100.

As such, since a concave lens may be formed on a light incident surface onto which light from the semiconductor light emitting device 131 is incident, by forming the groove portion 213 in the lens 212, light distribution of the semiconductor light emitting device 131 may be controlled more precisely.

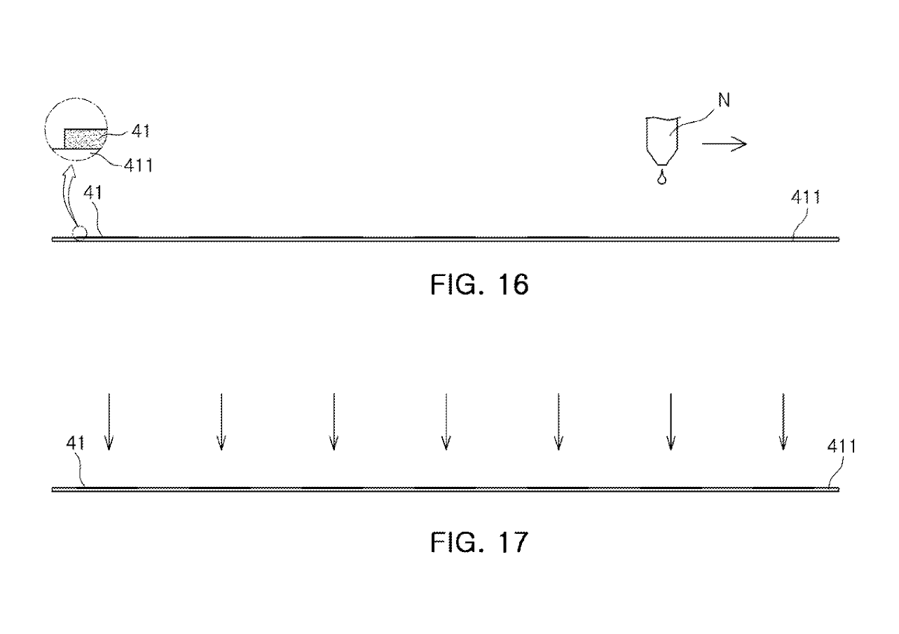

A method of manufacturing a lighting device according to another exemplary embodiment of the present inventive concept will be described below with reference to FIGS. 16 to 19. FIGS. 16 to 19 are views illustrating a manufacturing method of the lens portion of FIG. 5.

In the case of this exemplary embodiment of the present inventive concept, since the method of manufacturing a lighting device with reference to FIGS. 16 to 19 is only different from that of the foregoing exemplary embodiment of the present inventive concept in terms of a lens manufacturing method, this difference will be mainly described below and overlapped descriptions will be omitted.

First, a plurality of sub-layers may be sequentially stacked on a light transmitting sheet 411 in a perpendicular direction with regard to the light transmitting sheet 411, to then be cured and thereby form a plurality of lenses.

In detail, as illustrated in FIG. 16, a liquid-phase resin may be applied to one surface of the light transmitting sheet 411 to have a form of the sub-layer for formation of a lens using a jetting nozzle N. Here, the jetting nozzle N may be a printer nozzle. The sub-layer of the lens may refer to a surface obtained by cutting the lens to be parallel with regard to the light incident surface, and may be configured of a plurality of liquid droplets sprayed by the jetting nozzle N. Therefore, a thickness of a respective sub-layer may be determined by a relative minimum amount of liquid droplets able to be sprayed by the jetting nozzle N.

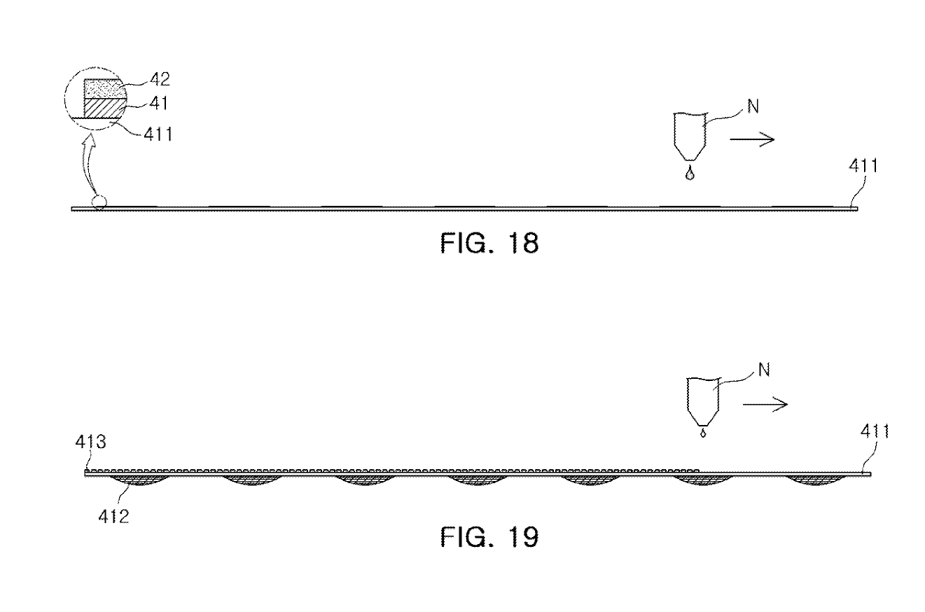

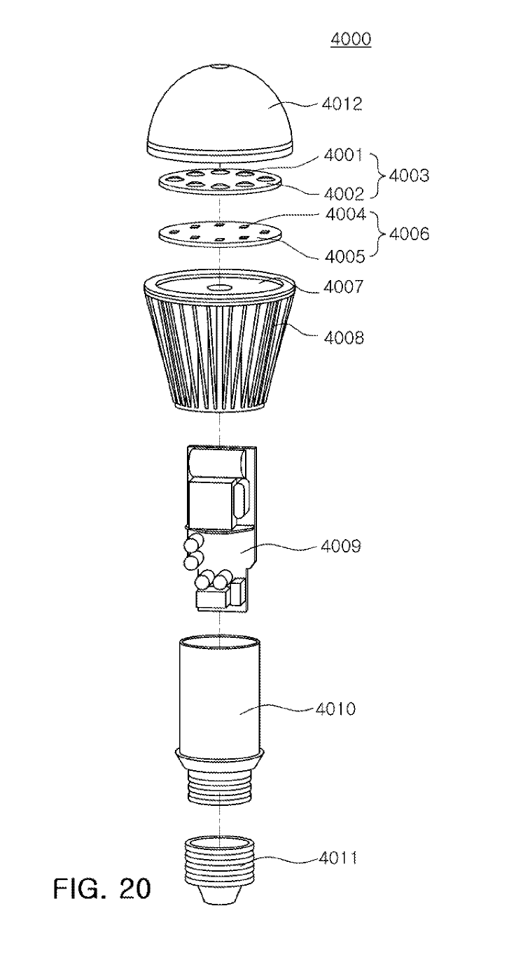

After a sub-layer 41 applied as above may be cured as illustrated in FIG. 17, an additional sub-layer 42 may be stacked on the cured sub-layer 41 as illustrated in FIG. 18. As such, by repetitively stacking the sub-layers 41 and 42 on each other, lens 412 as illustrated in FIG. 19 may be formed. In addition, a resin layer 413 may further be formed on the other surface of the light transmitting sheet 411.

Next, the light transmitting sheet 411 may be cut in a single direction to allow the plurality of lenses 412 to be aligned in a single direction. The light transmitting sheet 411 cut into predetermined units as above may be slidably coupled to the groove portion 122 of the body portion 120 described above with reference to FIG. 1 to thereby manufacture the lighting device 100.

When the lens 412 is manufactured by stacking a plurality of sub-layers on each other, since a separate mold may not be required, manufacturing costs of lighting devices may be reduced. In further detail, in the case of small quantity multiple type production required to variously change a lens shape, costs may be further decreased.

FIG. 20 is an exploded perspective view of a lighting device according to another exemplary embodiment of the present inventive concept. With reference to FIG. 20, a lighting device 4000 may be a bulb-type lamp and may include a light emitting module 4006, a lens portion 4003, a driving unit 4009, and an external connection unit 4011. In addition, the lighting device 4000 may further include an outer structure such as an external housing 4008, an internal housing 4010, and a cover unit 4012.

The light emitting module 4006 may include a semiconductor light emitting device 4004 having the same structure as, or a structure similar to, the semiconductor light emitting device 131 of FIG. 1, and a circuit board 4005 having the semiconductor light emitting device 4004 mounted thereon. Although this exemplary embodiment of the present inventive concept with reference to FIG. 20 illustrates the case in which eight semiconductor light emitting devices 4004 are mounted on the circuit board 4005, the amount of the semiconductor light emitting devices 4004 mounted thereon may be changed as needed. In addition, instead of directly mounting the semiconductor light emitting device 4004 on the circuit board 4005, the semiconductor light emitting device 4004 may be manufactured as a package type light emitting device and then mounted. The lens portion 4003 may be configured to include a light transmitting sheet 4002 and a lens 4001.

The external housing 4008 may serve as a heat radiating portion, and may include a heat radiating plate 4007 directly contacting the light emitting module 4006 to improve a heat radiation effect and include heat radiating fins disposed to encompass a peripheral surface of the lighting device 4000. The cover unit 4012 may be mounted on the light emitting module 4006 and may have a convex lens shape. The driving unit 4009 may be installed in the internal housing 4010 to be connected to the external connection unit 4011 having a structure such as a socket structure so as to receive power from an external power supply. In addition, the driving unit 4009 may convert the received power into a current source suitable for driving the semiconductor light emitting device 4004 of the light emitting module 4006 to then be supplied. For example, the driving unit 4009 may be configured of an AC-DC converter, a rectifying circuit component, or the like.

In addition, although not shown in FIG. 20, the lighting device 4000 may further include a communications module.

As set forth above, according to exemplary embodiments of the present inventive concept, since a lens may be formed on a light transmitting sheet using a liquid-phase resin, manufacturing of lighting devices may be facilitated, thereby reducing manufacturing costs.

While exemplary embodiments have been illustrated and described above, it will be apparent to those skilled in the art that modifications and variations could be made without departing from the spirit and scope of the present disclosure as defined by the appended claims.

What is claimed is:

1. A method of manufacturing a lighting device, comprising:
filling a plurality of first concave portions formed in one surface of a first mold by applying a first liquid-phase resin to the first mold;
attaching a light transmitting sheet to a surface of the first liquid-phase resin to cover the first liquid-phase resin filling the first concave portions;
forming a plurality of lenses on one surface of the light transmitting sheet by curing the first liquid-phase resin;
separating the light transmitting sheet on which the plurality of lenses are formed from the first mold;
cutting the light transmitting sheet into predetermined units to allow the plurality of lenses to be aligned in a single direction; and
preparing a light emitting module including a body portion containing a plurality of light emitting devices aligned in a single direction on one surface of the body portion and a groove portion spaced apart from the plurality of light emitting devices by a predetermined interval and extending in a single direction, and slidably coupling the cut light transmitting sheet to the groove portion so as to allow positions of the plurality of light emitting devices to be aligned with positions of the plurality of lenses.

2. The method of claim 1, further comprising:
after the step of the separating the light transmitting sheet from the first mold,
applying a second liquid-phase resin to a second mold including second concave portions formed in regions of the second mold corresponding to positions of the lenses formed from the first mold to fill the second concave portions; and
attaching an other surface of the light transmitting sheet to a surface of the second liquid-phase resin so as to allow positions of the lenses formed from the first mold to be aligned with positions of the second concave portions.

3. The method of claim 1, wherein the first liquid-phase resin is an ultraviolet (UV) curable resin.

4. The method of claim 3, wherein the step of forming the lenses comprises irradiating ultraviolet light to the first liquid-phase resin.

5. The method of claim 1, wherein the first liquid-phase resin is a silicone resin.

6. The method of claim 5, wherein the forming of the lenses comprises heating the first liquid-phase resin.

7. The method of claim 1, wherein the light transmitting sheet is formed using polycarbonate (PC) or polyethylene terephthlate (PET).

8. The method of claim 1, wherein the light transmitting sheet includes a through hole formed in a region of the light transmitting sheet corresponding to a position of the first concave portion.

9. The method of claim 8, wherein the step of forming the lenses is performed by coupling a jig having a convex portion disposed to correspond to a position of the through hole and curing the first liquid-phase resin.

10. The method of claim 1, wherein a refractive index of the first liquid-phase resin is different from a refractive index of the light transmitting sheet.

11. A method of manufacturing a lighting device, comprising:
forming a plurality of lenses by sequentially stacking a plurality of sub-layers on a light transmitting sheet in a perpendicular direction with regard to the light transmitting sheet;
cutting the light transmitting sheet in a single direction to allow the plurality of lenses to be aligned in a single direction; and
preparing a light emitting module including a body portion containing a plurality of light emitting devices aligned in a single direction on one surface of the body portion and a groove portion spaced apart from the plurality of light emitting devices by a predetermined interval and extending in a single direction, and slidably coupling the cut light transmitting sheet to the groove portion so as to allow positions of the plurality of light emitting devices to be aligned with positions of the plurality of lenses.

12. The method of claim 11, wherein the plurality of sub-layers are in parallel to light incident surfaces of the lenses.

13. The method of claim 11, wherein the plurality of sub-layers are formed by applying and curing the liquid-phase resin.

14. The method of claim 13, wherein the liquid-phase resin is a liquid-phase UV curable resin or a silicone resin.

15. The method of claim 13, wherein the light transmitting sheet is formed using polycarbonate (PC) or polyethylene terephthlate (PET).

16. A method of manufacturing a lamp, comprising:
manufacturing a plurality of lighting devices manufactured according to the method of claim 1;
preparing a light emitting module to include a circuit board and directly mounting the plurality of lighting devices on the circuit board;
preparing a heat radiating plate so that the light emitting module having the plurality of lighting devices mounted thereon is in direct contact with the heat radiating plate; and
mounting a cover unit on the light emitting module.

17. A method of manufacturing a lens portion, comprising:
forming a plurality of first lenses on a first surface of a light transmitting sheet;
filling a plurality of concave portions formed on a mold by applying a liquid-phase resin to the mold so that positions of the concave portions correspond to respective positions of the first lenses on the light transmitting sheet;
attaching a second surface of the light transmitting sheet to a surface of the liquid-phase resin so that the positions of the concave portions correspond to the respective positions of the first lenses on the light transmitting sheet; and
after attaching the second surface of the light transmitting sheet to the surface of the liquid-phase resin, forming a plurality of second lenses on the second surface of the light transmitting sheet by curing the liquid-phase resin.

18. The method of claim 17, further comprising:
separating, from the mold, the light transmitting sheet on which the plurality of first lenses and the plurality of second lenses are formed.

19. The method of claim 18, further comprising:
cutting the light transmitting sheet into predetermined units to allow the plurality of first lenses and the plurality of second lenses to be aligned in a single direction.

20. A method of manufacturing a lighting device, comprising:
manufacturing a light transmitting sheet according to the method of claim 19; and
preparing a light emitting module including a body portion containing a plurality of light emitting devices aligned in a single direction on one surface of the body portion and a groove portion spaced apart from the plurality of light emitting devices by a predetermined interval and extending in a single direction, and slidably coupling the light transmitting sheet to the groove portion so that positions of the plurality of light emitting devices correspond to respective positions of the plurality of first lenses.
